(19) United States
(12) Patent Application Publication
(10) Pub. No.: US 2009/0203529 A1
(43) Pub. Date: Aug. 13, 2009

(54) SUPERCONDUCTING MATERIAL

(76) Inventors: Colin David Tarrant, Cheshire (GB); Kelvin Robert Schneider, Wirral (GB); David Anthony Cardwell, Huntingdon (GB); Nadendla Hari Babu, Cambridge (GB)

Correspondence Address: TREGO, HINES & LADENHEIM, PLLC, 9300 HARRIS CORNERS PARKWAY, SUITE 210, CHARLOTTE, NC, 28269-3797, US

(21) Appl. No.: 11/995,475

(22) PCT Filed: Jul. 12, 2006
(86) PCT No.: PCT/GB2006/002591

§ 371 Date: Sep. 2, 2008

(30) Foreign Application Priority Data
Jul. 14, 2005 (GB) 0514504.0

(51) Int. Cl. H01B 12/06; H01L 39/24

(52) U.S. Cl. 505/237; 505/470; 427/62; 428/702

(57) ABSTRACT

There are provided superconducting materials (2) comprising a substrate (4); an interface layer (6) on the substrate, comprising a material of formula X_{w}BaₓCu_{y}LₜO_{z}, and a superconducting layer (8) on the interface layer comprising a compound of formula XₐBa_{b}Cu_{c}O_{d}− Also provided are methods of manufacturing superconducting materials and materials produced by these methods.

### FIELD OF THE INVENTION

This invention relates to superconducting material, and methods of manufacturing superconducting material.

### BACKGROUND TO THE INVENTION

Superconducting tapes generally consist of substrates on which are grown thin films of a superconducting layer. Superconducting tapes can efficiently carry large amounts of electrical current with minimal, or no, resistive losses. In many cases, a single, 1 cm wide high temperature superconducting tape can exhibit a current density up to 200 times that of an equivalent copper wire.

The market for superconducting tapes in electric power technologies is growing at a rapid pace, with the need for energy savings and emission reductions in power technologies of great concern. Electric motors, transformers, transmission cables and more obscure applications such as levitated trains, are some of the applications for which superconducting tapes are being used.

Current technology for the manufacture of thick or thin film superconducting tapes primarily uses one of two substrates; textured nickel substrates or silver-plated substrates treated to produce the cubic crystal structure on which to grow a superconducting layer.

Texturing of textured nickel substrates can be achieved by cold rolling, ion-beam bombardment or a mixture thereof. Texturing of silver-plated substrates may be achieved by electro-epitaxial deposition, as well as various ion plating processes in the case of silver and silver alloys.

One problem with current texturing techniques, including cold-rolling, ion-beam bombardment and electro-epitaxial deposition, is that they limit the temperature to which the substrate can be taken, in order to prevent the crystal structure of the substrate from changing during application of the superconducting layer. In the case of silver substrates, the oxygen content of the substrate also needs to be carefully controlled as this may cause a change in the configuration of the crystal structure of the substrate.

Attempts have been made to improve the structure of high temperature superconducting tapes, to produce tapes which exhibit superior current densities. A known improvement of superconducting tapes is the deposition of a buffer layer, between the substrate and the superconducting film, which allows growth of superior crystalline structures. One example is the use of a cubic zirconia buffer layer on a nickel alloy substrate, onto which is deposited a layer of yttrium barium copper oxide (YBCO), in which the zirconia layer is deposited using ion-beam assisted deposition. Subsequent laser deposition of the YBCO on top of the aligned zirconia allows growth of a crystalline superconducting film from 1 to 6 millionths of a metre thick.

However, the above-mentioned technique does not completely alleviate the problem of the limit of the temperature to which the substrate can be taken in order to prevent crystal structures from changing during application of the superconducting layer. The above-mentioned technique also does not address the problem of controlling oxygen content in the case of silver substrates.

It would be advantageous to provide a thick or thin film superconducting material or other superconducting material shape, in which a superconducting layer can be applied to a textured nickel or silver-based substrate, but in which the substrate can be taken up to temperatures in excess of 1000° C. during application of the superconducting layer, and in which the manufacturing process is relatively simple.

It would be furthermore advantageous to provide a method of manufacturing thin film superconducting materials in which the resultant material exhibits improved superconducting properties and stability compared to known thin film superconducting materials utilising known manufacturing methods.

It is therefore an aim of preferred embodiments of the present invention to overcome or mitigate at least one problem in the prior art, whether expressly disclosed herein or not.

### SUMMARY OF THE INVENTION

According to a first aspect of the invention, there is provided a superconducting material comprising:
(a) a substrate;
(b) an interface layer on the substrate, comprising a material of formula
   X_{w}BaₓCu_{y}LₜO_{z}

wherein X is selected from yttrium, neodymium, or one of the rare earth elements from group IIIB of the periodic table; L is one or more elements selected from U, Zr, Hf, Nb, Ta, Mo, W, Rh, Ir, Pd, Pt, Ag, Au, Sn, Pb, Sb, Bi, Ru and Ce, w is from 2 to 4; x is from 2 to 4; y is from 0 to 4; t is from 0.1 to 1, and z is from 2 to 16;
(c) a superconducting layer on the interface layer comprising a compound of formula
   XₐBa_{b}Cu_{c}O_{d}

wherein X is yttrium, neodymium or one of the rare earth elements from group IIIB of the periodic table; a is from 1 to 4; b is from 1 to 6; c is from 0.1 to 4, and d is from 2 to 22.

Preferably X is yttrium or neodymium.

Preferably w is 2, 3 or 4. Preferably x is 2, 3 or 4. Preferably y is from 0.1 to 4, more preferably from 0.1 to 3 and most preferably from 0.1 to 2. Preferably t is from 0.5 to 1. Preferably z is from 4 to 15.

Preferably a is 1, 2 or 3. Preferably b is from 2 to 4. Preferably c is 0.5 to 4, more preferably 0.5 to 2. Preferably d is from 3 to 20.

L will be chosen depending on the composition of the substrate and superconducting layer. For example, L may be silver when the substrate is silver or silver alloy. Preferably L is selected from Zr, Nb, W, Ag, Bi, Ce.

Preferably the substrate comprises nickel, silver or any combination thereof and is more preferably selected from Ni, Ni-5%W, Ni-10%Cr-2%W, HastelloyC-276, Ni—Ag, Ni_{0.7}Cu_{0.3}, Ni_{0.96}VO_{0.04} and Ni_{0.96}Cr_{0.02}V_{0.02}

Suitably the substrate has a thickness of 10 μm to 200μm

Suitably the interface layer comprises a compound of formula X₂Ba₄CuLO_{z}, more preferably X is yttrium.

Suitably the interface layer has a thickness of 10 nm to 800μm, preferably 10 nm to 1 μm

Suitably the superconducting layer comprises a compound of formula XBa₂Cu₃O, and more preferably X is yttrium.

Suitably the thickness of the superconducting layer is 250 nm to 100 μm with a preferred range of 300 nm to 10 μm.

The superconducting layer may comprise a compound of formula XₐBa_{b}Cu_{c}O_{d}, comprising a dopant of formula X_{w}BaₓCu_{y}LₜO_{z}, in which a, b, c, d, w, x, y, t and z are as described herein above, and X and L are as described herein above.

Suitably the dopant is in the form of a pinning centre, comprising dispersed crystals of X_{w}BaₓCu_{y}LₜO_{z} within the XₐBa_{b}Cu_{c}O_{d} superconducting crystal crystal structure.

Suitably in the dopant, w is selected from 2, 3 or 4, x is selected from 2, 3 or 4, y is from 0.1 to 3, t is from 0.5 to 1, and z is from 4 to 15. In preferred embodiments, the dopant comprises formula X₂Ba₄CuLO.

In particularly preferred embodiments, the superconducting layer comprises a compound of formula XBa₂Cu₃O, and the dopant pinning centre comprises a compound of formula X₂Ba₄CuLO_{z}.

There may be a contact layer applied to the superconducting layer. Suitably the contact layer comprises silver or a silver alloy. Other suitable materials for the contact layer include gold or gold alloys Preferably the contact layer has a thickness of between 1 μm to 10 μm with a preferred range of 1 μm to 3 μm.

There may be a plurality of alternate interface and superconducting layers.

For example, the superconducting material may comprise a substrate on which is applied alternate layers of X_{w}BaₓCu_{y}LₜO_{z} and XₐBa_{b}Cu_{c}O_{d}. A contact layer as described herein above may be applied to the uppermost layer of the alternate layers of X_{w}BaₓCu_{y}LₜO_{z} and XₐBa_{b}Cu_{c}O_{d}.

The initial X_{w}BaₓCu_{y}LₜO_{z} layer on the substrate acts as a seedbed for growth of the XₐBa_{b}Cu_{c}O_{d} layer, and a diffusion barrier to the XₐBa_{b}Cu_{c}O_{d} layer preventing its contamination by the substrate material.

According to a second aspect of the invention, there is provided a method of manufacturing a superconducting material comprising the steps of:
(a) providing a substrate;
(b) applying a layer of a compound of formula X_{w}BaₓCu_{y}LₜO_{z}, wherein X is selected from yttrium, neodymium, or one of the rare earth elements from group IIIB of the periodic table; L is one or more elements selected from U, Zr, Hf, Nb, Ta, Mo, W, Rh, Ir, Pd, Pt, Ag, Au, Sn, Pb, Sb, Bi, Ru and Ce, w is from 2 to 4; x is from 2 to 4; y is from 0 to 4; t is from 0.1 to 1, and z is from 2 to 16;
(c) applying a layer of superconducting material of formula XₐBa_{b}Cu_{c}O_{d}, wherein X is yttrium, neodymium or one of the rare earth elements from group IIIB of the periodic table; a is from 1 to 4; b is from 1 to 6; c is from 0.1 to 4, and d is from 2 to 22.

Suitably, a, b, c, d, w, x, y, t, z, X and L are as described herein above for the first aspect of the invention.

Suitably the interface layer applied in step (b) and the superconducting layer applied in step (c) are as described for the first aspect of the invention.

Preferably the method may comprise a step in between steps (a) and (b) of removing an oxide layer from the substrate. Removal of an oxide layer from the substrate may be performed by glow discharging with argon, in which the substrate is heated to a temperature of between 750° C. and 950° C., more preferably around 800° C.

Preferably step (b) comprises maintaining the substrate at a temperature of between 750° C. and 950° C., more preferably between 800° C. and 900° C., and most preferably around 850° C., during application of the interface layer.

Preferably step (c) comprises maintaining a temperature of the coated substrate at between 750° C. and 950° C., more preferably between 800° C. and 900° C., and most preferably around 850° C., during application of the superconducting layer.

Preferably the method comprises a step (d) of oxygenating the superconducting layer after step (c).

Preferably the method comprises a step after step (d) of cooling the coated substrate and purging the surface of the substrate with a Nobel gas, preferably argon.

Preferably the method comprises a step after step (c) and, when present, after step (d), of applying a layer of contact material to the coated substrate. Preferably the contact material is silver or a silver alloy. The contact material may be as described herein above for the first aspect of the invention.

Heating of the substrate or coated substrate may be achieved by passing a current through the substrate or coated substrate.

The method may comprise repeating steps (b) and (c), such that a plurality of alternate layers of X_{w}BaₓCu_{y}LₜO_{z} and XₐBa_{b}Cu_{c}O_{d} are coated onto the substrate. When utilised, steps (d) and (e) may be performed after repetition of steps (b) and (c), preferably after all repetitions of steps (b) and (c).

Therefore, in a preferred embodiment of the method of the second aspect of the invention, the method comprises the steps of:
(a) providing a substrate;
(b) applying a layer of X_{w}BaₓCu_{y}LₜO_{z};
(c) applying a layer of XₐBa_{b}Cu_{c}O_{d} to the X_{w}BaₓCu_{y}LₜO_{z} layer;
(d) repeating steps (b) and (c) at least one further time;
(e) coating the coated substrate with a contact layer.

Each layer of XₐBa_{b}Cu_{c}O_{d} may be oxygenated before applying a layer of X_{w}BaₓCu_{y}LₜO_{z} thereon.

Suitably the method is performed at a pressure of at least 1 Pa, and more preferably at least 1.5 Pa, most preferably at least 2 Pa.

According to a third aspect of the invention, there is provided a superconducting material of the first aspect of the invention, manufactured by the method of the second aspect of the invention.

The superconducting material may comprise a superconducting wire, tape or the like, for example.

Suitably, the total thickness of the superconducting material is no more than substantially 100 μm for thick film applications and 15 μm for wires and tapes. Suitably, the total thickness of the superconducting material is at least 100 nm.

### BRIEF DESCRIPTION OF THE DRAWING

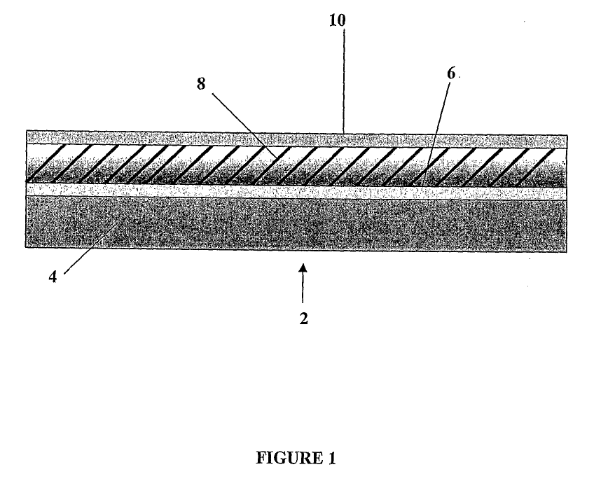

For a better understanding of the invention, and to show how embodiments of the same may be put into effect, the various aspects of the invention will now be described by way of the accompanying FIG. 1, which illustrates a superconducting material of the first aspect of the invention, manufactured by a method of the second aspect of the invention.

### DESCRIPTION OF THE PREFERRED EMBODIMENT

We refer firstly to FIG. 1.

FIG. 1 illustrates a first embodiment of a superconducting material 2 comprising a substrate 4 on which is located an interface layer 6. A superconducting layer 8 has been grown on the interface layer 6, and a contact layer 10 has been coated on the superconducting layer 8.

The substrate 2 comprises pure nickel wire/tape that has preferably been roll formed and heat treated to give the desired aligned cubic crystal structure on the surfaces but not necessarily rolled. The nickel wire has a thickness of approximately 100 μm. The interface layer comprises Y₂Ba₄CuAgO (Y2411 material). The interface layer comprises a thickness of 11 nm. The Y2411 material was synthesised by the Interdisciplinary Research Centre, Cambridge. It was synthesised by mixing Y₂O₃, BaCu₃, CuO, Ag₂O in the required molar ratios and calcining at 900° C. for 12 hours, 950° C. for 12 hours, 1000° C. for 12 hours with intermediate grinding/milling operations. Phase purity was checked by X-ray diffraction techniques.

The superconducting layer 8 comprises YBa₂Cu₃O (Y123 material), and consists of a layer having a thickness of 1 μm. The Y123 material was supplied by the Interdisciplinary Research Centre, Cambridge. It was synthesised by mixing Y₂O₃, BaCu₃, CuO powder in the required molar ratios and calcining at 880° C. for 12 hours, 900° C. for 12 hours, 920° C. for 12 hours.

The contact layer 10 comprises silver, and has a thickness of 10 μm.

The superconducting wire 2 was manufactured as follows.

The nickel substrate 4 was degreased to remove any traces of hydrocarbon. Any nickel oxide present on the substrate surface was removed by glow discharging with argon gas at a pressure of 2 Pa, and at a temperature of approximately 800° C.

The nickel substrate 2 was then sputter-coated with a Y2411 layer 6 of 10 nm thick to act as a seedbed for growth of the Y123 superconducting layer 8 and a diffusion barrier to the Y123 preventing its contamination by the substrate 2. Sputter coating of the Y2411 interface layer 6 was performed at a pressure of 2 Pa and at a temperature of approximately 850° C. Unbalanced closed field Magnetron Sputtering equipment designed and developed by Teer Coatings Ltd. UK was used. The interface layer 6 was then coated at 850° C. with a layer 8 of Y123 in an oxygen-rich environment. Thus the resultant Y123 coating was oxygenated. A temperature of approximately 850° C. was maintained in order to allow crystal formation of the Y123 layer 8.

The coated substrate 2 was then cooled to 500° C. and purged with argon gas at a pressure of approximately 2 Pa. The Y123 superconducting layer 8 was then coated with a layer of silver to provide the contact layer 10, and complete the process. The resultant superconducting wire 2 was then allowed to cool to room temperature.

In alternative embodiments, after coating the Y123 superconducting layer 8 on the Y2411 interface layer 6, further alternate layers of Y2411 interface layers 6 preferably 10 nm thick and Y123 superconducting layers 8 preferably 1 nm thick may be added, preferably up to a total thickness of 10 μm for all the Y123 and Y2411 layers combined. Each Y123 superconducting layer 8 is oxygenated as described above before coating with a Y2411 interface layer 6.

In alternative embodiments, the materials used in the substrate 4, interface layer 6 and superconducting layer 8 may be altered as desired. For example, the Y₂Ba₄CuAgO interface layer 6 may be replaced with X_{w}BaₓCu_{y}LₜO_{z} materials, wherein X is selected from yttrium, neodymium or a rare earth element of group IIIB, and L is an element selected from U, Zr, Hf, Nb, Ta, Mo, W, Rh, Ir, Pd, Pt, Ag, Au, Sn, Pb, Sb, Bi, Ru and Ce, w is from 2 to 4, x is from 2 to 4, y is from 0 to 4, t is from 0.1 to 1 and z is from 2 to 16. Likewise the superconducting layer 8 material YBa₂Cu₃O may be replaced with XₐBa_{b}Cu_{c}O_{d}, wherein x is yttrium, neodymium, or one of the rare earth elements from group IIIB, a is 1 to 4, b is 1 to 6, c is 0.1 to 4 and d is 2 to 22. The substrate 4 may comprise a nickel alloy such as a nickel copper alloy, a silver substrate or a silver alloy substrate, for example. The superconducting layer 8 may include pinning centres of non-superconducting material, especially Y2411 material.

The thicknesses of each of the layers 4, 6, 8 and 10 may be adjusted as desired to effect differing superconducting properties and characteristics on the superconducting material 2. The physical form of the superconducting material 2 may for example be a thin film, a wire, a sheet, or tape, for example.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extend to any novel one, or any novel combination, of the features disclosed in this specification (including any accompanying claims, abstract and drawings), or to any novel one, or any novel combination, of the steps of any method or process so disclosed.

1. A superconducting material comprising:
(a) a substrate;
(b) an interface layer on the substrate, comprising a material of formula
X_{w}BaₓCu_{y}LₜO_{z}
wherein X is selected from yttrium, neodymium, or one of the rare earth elements from group IIIB of the periodic table; L is one or more elements selected from U, Zr, Hf, Nb, Ta, Mo, W, Rh, Ir, Pd, Pt, Ag, Au, Sn, Pb, Sb, Bi, Ru and Ce, w is from 2 to 4; x is from 2 to 4; y is from 0 to 4; t is from 0.1 to 1, and z is from 2 to 16; and
(c) a superconducting layer on the interface layer comprising a compound of formula
XₐBa_{b}Cu_{c}O_{d}
wherein X is yttrium, neodymium or one of the rare earth elements from group IIIB of the periodic table; a is from 1 to 4; b is from 1 to 6; c is from 0.1 to 4, and d is from 2 to 22.

2. A material according to claim 1, wherein X is yttrium or neodymium.

3. A material according to claim 1, wherein w is 2, 3 or 4, x is 2, 3 or 4, y is from 0.1 to 4, t is from 0.5 to 1, z is from 4 to 15, a is 1, 2 or 3, b is from 2 to 4, c is 0.5 to 4 and d is from 3 to 20.

4. A material according to claim 1, wherein L is selected from the group consisting of Zr, Nb, W, Ag, Bi, and Ce.

5. A material according to claim 1, wherein the substrate comprises, nickel, silver or any combination thereof.

6. A material according to claim 1, wherein the substrate has a thickness of 10 μm to 200 μm, the interface layer has a thickness of 10 nm to 800 μm and the thickness of the superconducting layer is 250 nm to 100 μm.

7. A material according to claim 1, wherein the superconducting layer comprises a compound of formula XₐBa_{b}Cu_{c}O_{d}, further comprising a dopant of formula X_{w}BaₓCu_{y}LₜO_{z}, in which a, b, c, d, w, x, y, t and z are as described in claim 1, and X and L are as described in claim 1.

8. A material according to claim 7, wherein the superconducting layer comprises a compound of formula XBa₂Cu₃O, and the material comprises a dopant pinning centre which comprises a compound of formula X₂Ba₄CuLO_{z}.

9. A material according to claim 1, wherein there is a contact layer applied to the superconducting layer.

10. A material according to claim 1, wherein there are a plurality of alternate interface and superconducting layers.

11. A method of manufacturing a superconducting material comprising the steps of:
(a) providing a substrate;
(b) applying to the substrate an interface layer of a compound of formula X_{w}BaₓCu_{y}LₜO_{z}, wherein X is selected from yttrium, neodymium, or one of the rare earth elements from group IIIB of the periodic table; L is one or more elements selected from U, Zr, Hf, Nb, Ta, Mo, W, Rh, Ir, Pd, Pt, Ag, Au, Sn, Pb, Sb, Bi, Ru and Ce, w is from 2 to 4; x is from 2 to 4; y is from 0 to 4; t is from 0.1 to 1, and z is from 2 to 16;
(c) applying to the interface layer a superconducting layer of superconducting material of formula XₐBa_{b}Cu_{c}O_{d}, wherein X is yttrium, neodymium or one of the rare earth elements from group IIIB of the periodic table; a is from 1 to 4; b is from 1 to 6; c is from 0.1 to 4, and d is from 2 to 22.

12. (canceled)

13. A method according to claim 11, wherein the method comprises a step in between steps (a) and (b) of removing an oxide layer from the substrate.

14. A method according to claim 11, wherein step (b) comprises maintaining the substrate at a temperature of between 750° C. and 950° C. and step (c) comprises maintaining a temperature of the coated substrate at between 750° C. and 950° C.

15. A method according to claim 11, wherein the method comprises a step (d) of oxygenating the superconducting layer after step (c).

16. A method according to claim 11, wherein the method comprises a step after step (c) and, when present, after step (d), of applying a layer of contact material to the coated substrate.

17. A method according to claim 11, wherein the method comprises the steps of:
(a) providing a substrate;
(b) applying a layer of X_{w}BaₓCu_{y}LₜO_{z};
(c) applying a layer of XₐBa_{b}Cu_{c}O_{d} to the X_{w}BaₓCu_{y}LₜO_{z} layer;
(d) repeating steps (b) and (c) at least one further time;
(e) coating the coated substrate with a contact layer.

18. A superconducting material according to claim 1 manufactured by the method of claim 11.
